(19) United States
(12) Patent Application Publication
(10) Pub. No.: US 2019/0165193 A1
(43) Pub. Date: May 30, 2019

(54) PHOTOVOLTAIC MODULE AND PHOTOVOLTAIC SYSTEM INCLUDING THE SAME

(71) Applicant: LG ELECTRONICS INC., Seoul (KR)

(72) Inventors: Hyeonggu HAN, SEOUL (KR); Kanghwi KIM, SEOUL (KR); Daihyun KIM, SEOUL (KR); Yesl SHIN, SEOUL (KR); Sunho YU, SEOUL (KR); Kanghwan JIN, SEOUL (KR)

(73) Assignee: LG ELECTRONICS INC., Seoul (KR)

(21) Appl. No.: 16/203,065

(22) Filed: Nov. 28, 2018

(30) Foreign Application Priority Data
Nov. 28, 2017 (KR) 10-2017-0160839

(51) Int. Cl. H01L 31/047; H02J 3/38; H02M 7/44

(52) U.S. Cl. CPC H01L 31/047; H02M 7/44; H02J 3/383

(57) ABSTRACT

The present invention relates to a photovoltaic module and a photovoltaic system including the same. A photovoltaic module and a photovoltaic system including the same include a solar cell module including a plurality of solar cells, a junction box to convert DC power from the solar cell module to AC power, a first cable through which the AC power from the junction box is output to an outside, and a second cable connected to a controller in the junction box for output or input of communication data. Accordingly, data communication can be easily performed using the controller in the photovoltaic module.

### CROSS-REFERENCE TO RELATED APPLICATION

This application claims priority to Korean Patent Application No. 10-2017-0160839, filed on Nov. 28, 2017 in the Korean Intellectual Property Office, the disclosure of which is incorporated herein by reference.

### BACKGROUND OF THE INVENTION

### 1. Field of the Invention

The present invention relates to a photovoltaic module and a photovoltaic system including the same, and more specifically, to a photovoltaic module capable of easily performing data communication using a controller included therein and a photovoltaic system including the same.

### 2. Description of the Related Art

As depletion of energy resources, such as petroleum and coal, is expected recently, interest in alternative energy has increased. A solar cell is spotlighted as a next-generation battery that directly converts solar energy into electric energy using a semiconductor device.

In addition, a photovoltaic module refers to solar cells connected in series or parallel for photovoltaic power generation.

When a photovoltaic module outputs AC power, the photovoltaic module performs communication with a gateway through power line communication. However, a communication unit needs to be connected to the ground for power line communication, and thus it is difficult to install the photovoltaic module.

### SUMMARY OF THE INVENTION

Therefore, the present invention has been made in view of the above problems, and it is an object of the present invention to provide a photovoltaic module capable of easily performing data communication using a controller included therein and a photovoltaic system including the same.

Another object of the present invention is to provide a photovoltaic module without a communication unit included therein and a photovoltaic system including the same.

In accordance with an aspect of the present invention, the above and other objects can be accomplished by the provision of a photovoltaic module including: a solar cell module including a plurality of solar cells; a junction box to convert DC power from the solar cell module to AC power; a first cable through which the AC power from the junction box is output to an outside; and a second cable connected to a controller in the junction box for output or input of communication data.

In accordance with another aspect of the present invention, there is provided a photovoltaic system including: a plurality of photovoltaic modules to output AC power to a grid; and a gateway to perform data communication with the plurality of photovoltaic modules, wherein each photovoltaic module includes: a solar cell module including a plurality of solar cells; a junction box to convert DC power from the solar cell module to AC power; a first cable through which the AC power from the junction box is output to an outside; and a second cable connected to a controller in the junction box for output or input of communication data.

In accordance with another aspect of the present invention, there is provided a photovoltaic system including: a plurality of photovoltaic modules to output AC power to a grid; a communication device to perform data communication with the plurality of photovoltaic modules; and a gateway to perform data communication with the communication device, wherein each photovoltaic module includes: a solar cell module including a plurality of solar cells; a junction box to convert DC power from the solar cell module to AC power; a first cable through which the AC power from the junction box is output to an outside; and a second cable connected to a controller in the junction box and used for output/input of communication data to/from the communication device.

### BRIEF DESCRIPTION OF THE DRAWINGS

The above and other objects, features and other advantages of the present invention will be more clearly understood from the following detailed description taken in conjunction with the accompanying drawings, in which:

FIG. 1A is a diagram showing an example of a photovoltaic system including a photovoltaic module according to an embodiment of the present invention;

FIG. 1B is a diagram showing another example of a photovoltaic system including a photovoltaic module according to an embodiment of the present invention;

FIG. 2 is a front view of the photovoltaic module according to an embodiment of the present invention;

FIG. 3 is a rear view of the photovoltaic module of FIG. 2;

FIG. 4A is a diagram showing a photovoltaic system related to the present invention;

FIGS. 4B and 4C are diagrams referred to for description of FIG. 4A;

FIG. 5 is a circuit diagram of the junction box in the photovoltaic module shown in FIG. 2;

FIGS. 6 to 8C are diagrams referred to for description of FIG. 5;

FIG. 9 is a diagram showing a photovoltaic system according to another embodiment of the present invention;

FIG. 10 is a diagram referred to for description of FIG. 9;

FIGS. 11A to 11E are diagrams referred to for describing an operation of the photovoltaic system illustrated in FIG. 9; and

FIG. 12 is an exploded perspective view of the photovoltaic module shown in FIG. 2.

### DETAILED DESCRIPTION OF THE EMBODIMENTS

The present invention proposes a method for reducing ripples in current input to a converter in a photovoltaic module. The present invention will be described in more detail with reference to the drawings. The suffixes “module” and “unit” of elements herein are used for convenience of description and need not have any distinguishable meanings or functions. Accordingly, the suffixes “module” and “unit” can be used interchangeably.

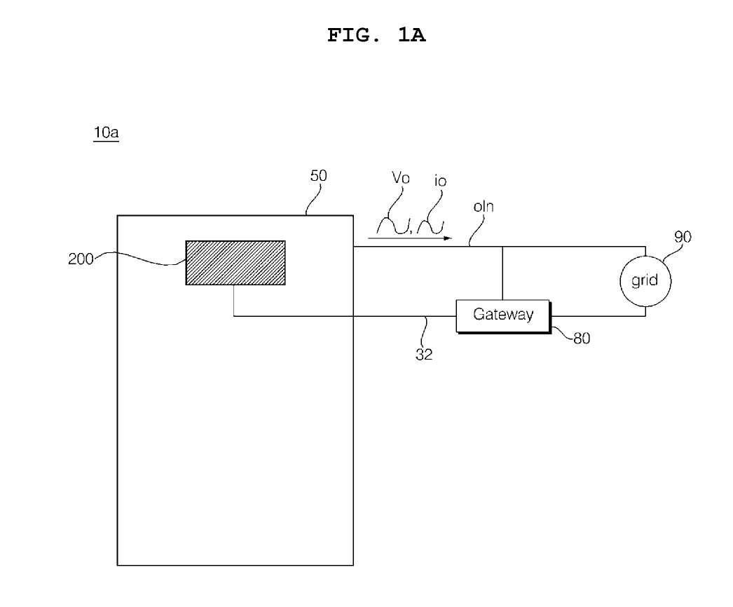

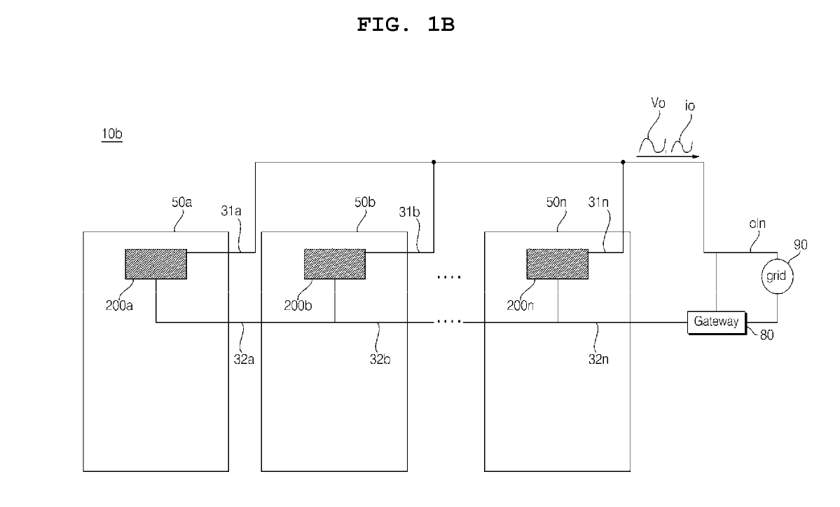

FIG. 1A is a diagram showing an example of a photovoltaic system including a photovoltaic module according to an embodiment of the present invention. Referring to FIG. LA, a photovoltaic system 10a according to an embodiment of the present invention can include a photovoltaic module 50 and a gateway 80.

The photovoltaic module 50 can include a solar cell module 100, a junction box 200 including a power conversion device (500 in FIG. 5) which converts DC power in the solar cell module and outputs the converted power, a first cable through which AC power from the junction box 200 is output to the outside, and a second cable 32 connected to a controller (550 in FIG. 5) included in the junction box 200 and used for output or input of communication data. Accordingly, it is possible to easily perform data communication using the controller 550 included in the photovoltaic module 50 without an additional communication unit.

The controller 550 performs data communication with the neighboring photovoltaic module 50 or the gateway 80. A signal output from the controller 550 can be a differential signal. Accordingly, data communication can be easily performed without an additional communication unit.

The controller 550 can output communication data including AC voltage information and AC information on AC power to be output through the second cable 32, thereby easily outputting information on the photovoltaic module 50 which is an AC module.

Although the junction box 200 is attached to the rear side of the solar cell module 100 in the figure, the present invention is not limited thereto. The junction box 200 can be separate from the solar cell module 100.

The first cable 31 through which AC power output from the junction box 200 is output to the outside can be connected to a grid cable oln connected to a grid 90. The second cable 32 can be connected to the gateway 80. Accordingly, data communication can be performed between the photovoltaic module 50 and the gateway 80.

Particularly, the photovoltaic module 50 can perform a controller area network (CAN) communication instead of a conventional power line communication (PLC). In this manner, CAN communication is performed using the controller 550 of the photovoltaic module 50. Accordingly, an additional communication unit and the ground necessary for PLC are not needed, and thus the photovoltaic module 50 can be easily installed.

The gateway 80 can be positioned between the junction box 200 and the grid 90. The gateway 80 can detect an AC current io and an AC voltage vo output from the photovoltaic module 50 through the cable oln.

The power conversion device (500 in FIG. 5) included in the photovoltaic module 50 can convert DC power output from the solar cell module 100 into AC power and output the AC power. To this end, the power conversion device (500 in FIG. 5) in the photovoltaic module 50 can include a converter (530 in FIG. 5) and an inverter (540 in FIG. 5).

FIG. 1B is a diagram showing another example of a photovoltaic system including a photovoltaic module according to an embodiment of the present invention. Referring to FIG. 1B, a photovoltaic system 10b according to an embodiment of the present invention can include a plurality of photovoltaic modules 50a, 50b, 50n and the gateway 80.

The photovoltaic system 10b of FIG. 1B differs from the photovoltaic system 10a of FIG. 1A in that the photovoltaic modules 50a, 50b, . . . , 50n are connected in parallel. The photovoltaic modules 50a, 50b, . . . , 50n can respectively include solar cell modules 100a, 100b, . . . , 100n, junction boxes 200a, 200b, . . . , 200n including circuit elements for converting DC power in the solar cell modules and outputting the converted power, first cables 31a, 31b, . . . , 31n through which AC power from the junction boxes 200a, 200b, . . . , 200n is output to the outside, and second cables 32a, 32b, . . . , 32n connected to controllers 550a, 550b, . . . , 550n included in the junction boxes 200a, 200b, . . . 200n and used for output or input of communication data. Accordingly, it is possible to easily perform data communication using the controllers 550a, 550b, . . . , 550n included in the photovoltaic modules 50a, 50b, . . . , 50n without an additional communication unit.

The first cables 31a, 31b, . . . , 31n through which AC power output from the junction boxes 200a, 200b, . . . , 200n is output to the outside can be connected to a grid cable oln connected to a grid 90. The second cables 32a, 32b, . . . , 32n can be respectively connected to the junction boxes 200a, 200b, . . . , 200n of neighboring photovoltaic modules, and the nth-cable 32n closest to the gateway 80 can be connected to the gateway 80. Accordingly, data communication can be performed between the photovoltaic modules 50a, 50b, . . . , 50n and the gateway 80.

Particularly, the photovoltaic modules 50a, 50b, . . . , 50n can perform CAN communication instead of a conventional PLC. In this manner, CAN communication is performed using the controllers 550a, 550b, . . . , 550n in the photovoltaic modules 50a, 50b, . . . , 50n. Accordingly, an additional communication unit and the ground necessary for PLC are not needed, and thus the photovoltaic modules 50a, 50b, . . . , 50n can be easily installed.

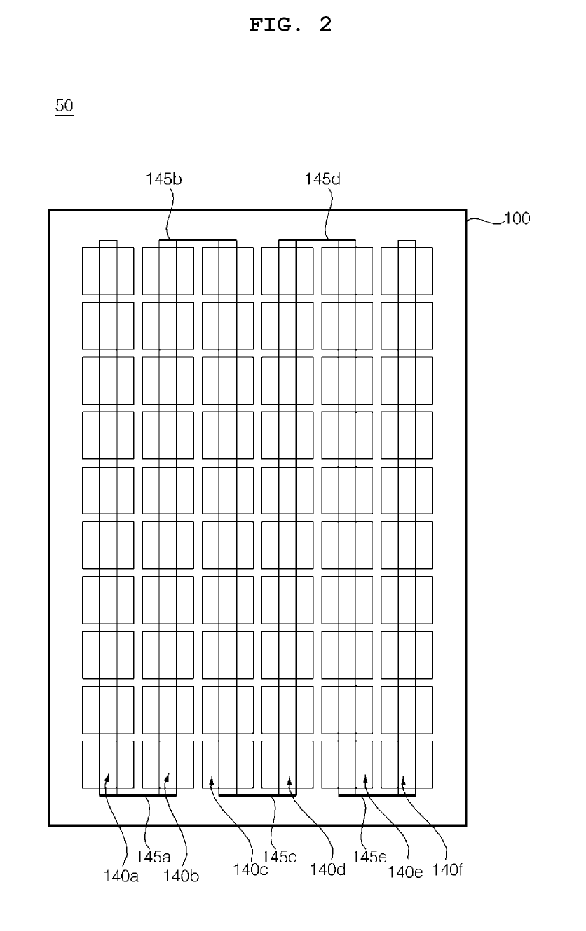

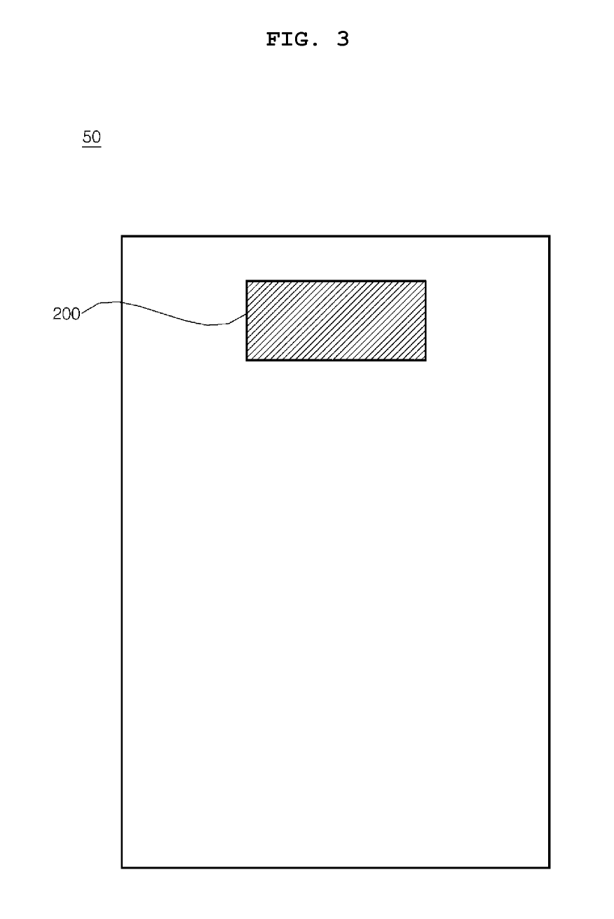

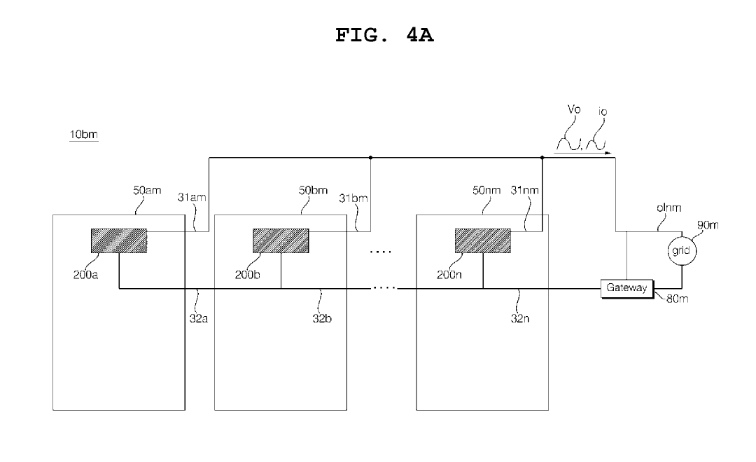

FIG. 2 is a front view of the photovoltaic module according to an embodiment of the present invention and FIG. 3 is a rear view of the photovoltaic module of FIG. 2. Referring to the figures, the photovoltaic module 50 according to an embodiment of the present invention can include the solar cell module 100 and the junction box 200 provided on the rear side of the solar cell module 100. The junction box 200 can include at least one bypass diode for preventing a hot spot in the case of occurrence of a shading.

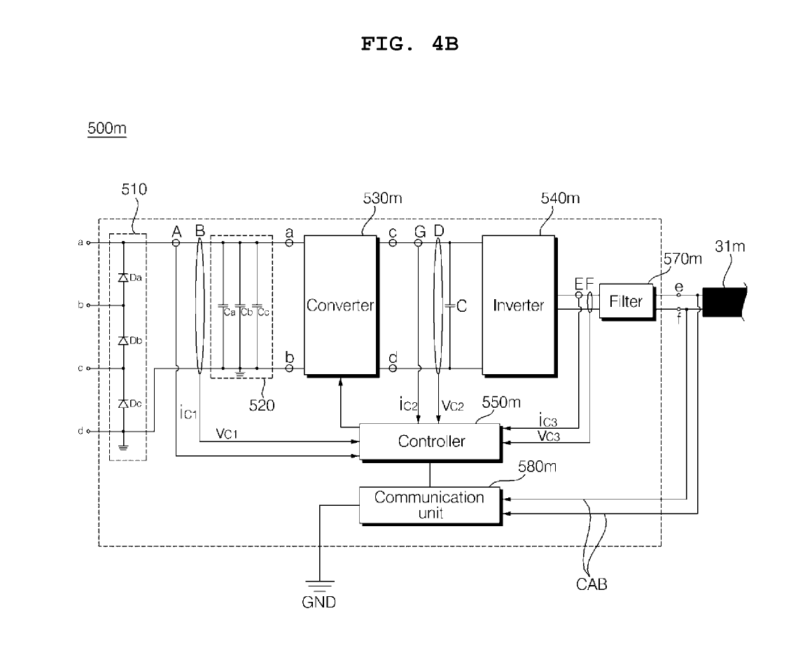

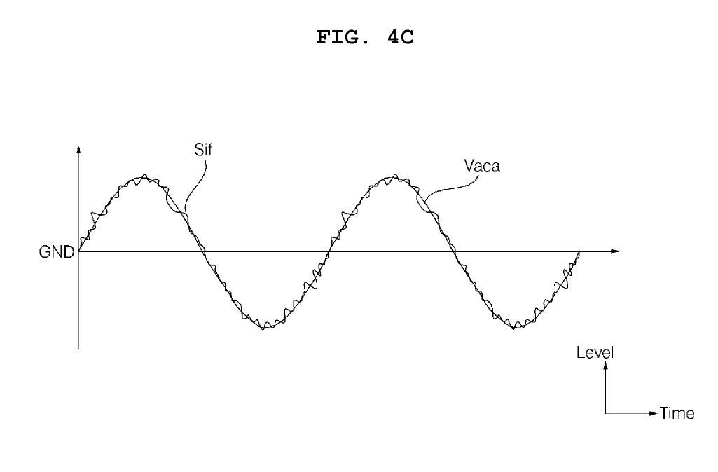

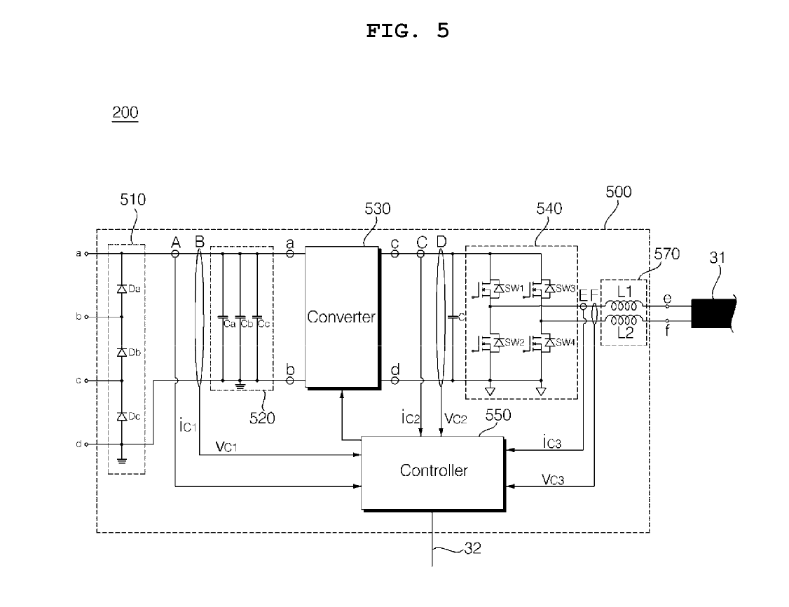

FIG. 5 shows that the junction box 200 includes three bypass diodes Da, Db and Dc corresponding to four solar cell strings of FIG. 2. In addition, the junction box 200 can convert DC power supplied from the solar cell module 100. This will be described with reference to FIG. 4 and the following figures.

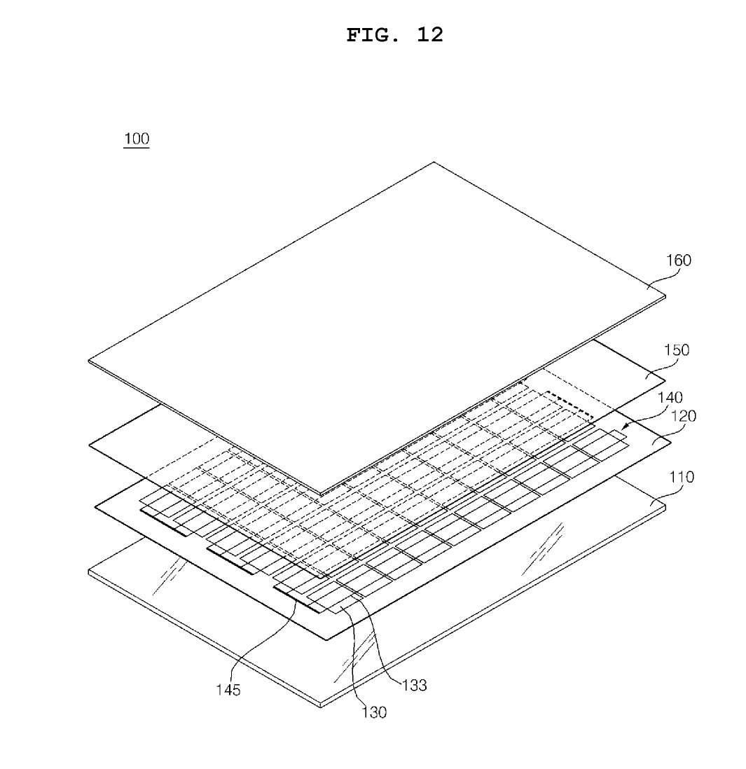

The solar cell module 100 can include a plurality of solar cells. The solar cells are connected in a line by means of a ribbon (133 in FIG. 12) to form solar cell strings 140. In this manner, six strings 140a, 140b, 140c, 140d, 140e and 140f are formed and each string includes ten solar cells, for example. Arrangement of solar cells can be modified in various manners from that shown in the figure.

The solar cell strings can be electrically connected through bus ribbons. FIG. 2 shows that the first solar cell string 140a is electrically connected to the second solar cell string 140b, the third solar cell string 140c is electrically connected to the fourth solar cell string 140d, and the fifth solar cell string 140e is electrically connected to the sixth solar cell string 140f through bus ribbons 145a, 145c and 145e arranged at the lower part of the solar cell module 100, respectively.

In addition, FIG. 2 shows that the second solar cell string 140b is electrically connected to the third solar cell string 140c and the fourth solar cell string 140d is electrically connected to the fifth solar cell string 140e through bus ribbons 145b and 145d arranged at the upper part of the solar cell module 100, respectively.

The ribbon connected to the first solar cell string 140a, the bus ribbons 145b and 145d, and the ribbon connected to the fourth solar cell string 140d are respectively electrically connected to first to fourth conductive lines, and the first to fourth conductive lines can be connected to the bypass diodes (Da, Db and Dc in FIG. 4) in the junction box 200 provided on the rear side of the solar cell module 100 through an opening formed in the solar cell module 100.

Here, the opening formed in the solar cell module 100 can be formed to correspond to the region in which the junction box 200 is positioned.

FIG. 4A is a diagram showing a photovoltaic system related to the present invention and FIGS. 4B and 4C are diagrams referred to for description of FIG. 4A. Referring to FIG. 4A, a photovoltaic system 10bm can include a plurality of photovoltaic modules 50am, 50bm, . . . , 50nm and a gateway 80m.

The photovoltaic modules 50am, 50bm, . . . , 50nm perform PLC distinguished from FIGS. 1A and 1B. Accordingly, cables 31am, 31bm, 31nm through which AC power is output can be respectively connected to the photovoltaic modules 50am, 50bm, . . . , 50nm and can be connected to a grid cable olnm, connected to a grid 90m.

As shown in FIG. 4B, each of the photovoltaic modules 50am, 50bm, . . . , 50nm can include a power conversion device 500m including a converter 530m, an inverter 540m, a controller 550m and a communication unit 580m.

The communication unit 580m can output a signal for PLC to output terminals of a filter 570m through internal cables CAB. Accordingly, the signal for PLC can be added to AC power output from the filter 570m and output through the cable 31m.

FIG. 4C shows an AC voltage Vaca to which a PLC signal Sif has been added according to PLC. To perform such PLC, the additional communication unit 580m as shown in FIG. 4B is required and the communication unit 580 needs to be connected to the ground GND to generate a PLC signal having positive polarity and negative polarity.

To solve such a problem, the present invention employs CAN communication using a controller without a communication unit instead of PLC. Accordingly, it is desirable that a cable through which AC power is output from the photovoltaic module 50 differ from a cable for performing CAN communication. This will be described below with reference to FIG. 5 and the following figures.

FIG. 5 is a diagram showing an internal circuit of the junction box in the photovoltaic module of FIG. 2. Referring to FIG. 5, the junction box 200 can convert DC power from the solar cell module 100 and output the converted power.

Particularly, the junction box 200 according to the present invention can include the power conversion device (500 in FIG. 5) for outputting AC power. To this end, the junction box 200 can include the converter 530, the inverter 540 and the controller 550 for controlling the same.

In addition, the junction box 200 can further include a bypass diode unit 510 for bypass, a capacitor unit 520 for storing DC power, and a filter 570 for filtering output AC power. Further, the junction box 200 can further include an input current detector A, an input voltage detector B, a converter output current detector C, a converter output voltage detector D, an inverter output current detector E and an inverter output voltage detector F.

The controller 550 can control the converter 530 and the inverter 540. The bypass diode unit 510 can include the bypass diodes Dc, Db and Da arranged between the first to fourth conductive lines of the solar cell module 100. Here, the number of bypass diodes is one or more, for example, less than the number of conductive lines by one.

The bypass diodes Dc, Db and Da receive photovoltaic DC power from the solar cell module 100, particularly, from the first to fourth conductive lines in the solar cell module 100. When a reverse voltage is generated in DC power from at least one of the first to fourth conductive lines, the bypass diodes Dc, Db and Da can bypass the DC power.

DC power which has passed through the bypass diode unit 510 can be input to the capacitor unit 520. The capacitor unit 520 can store the DC power input through the solar cell module 100 and the bypass diode unit 510.

Although the figure shows that the capacitor unit 520 includes a plurality of capacitors Ca, Cb and Cc connected in parallel, a plurality of capacitors can be connected in series and parallel or connected in series to a ground terminal. Alternatively, the capacitor unit 520 can include only one capacitor.

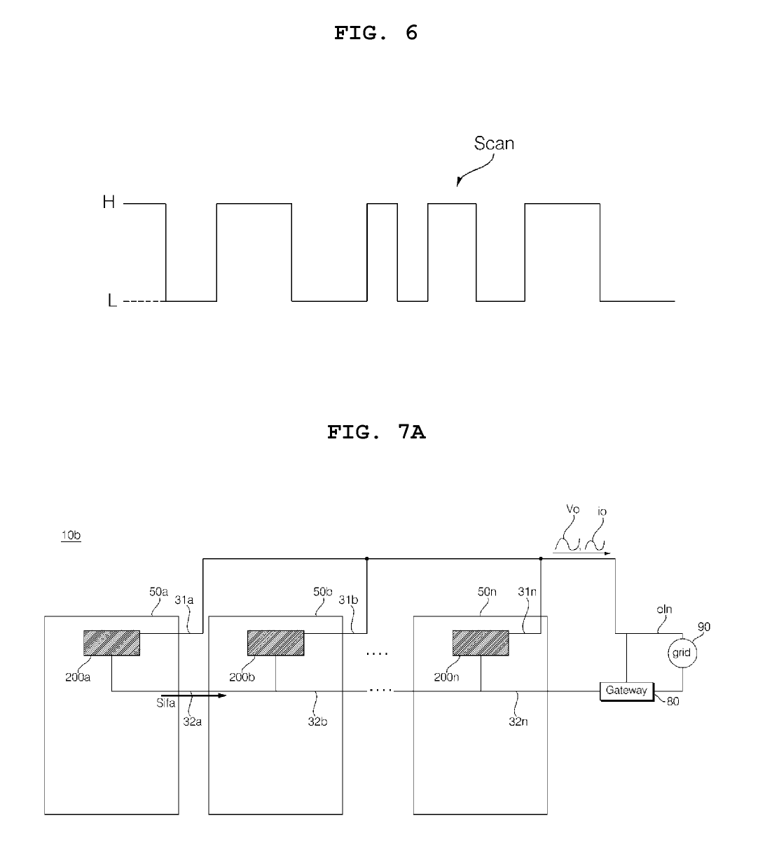

The converter 530 can convert the level of an input voltage from the solar cell module 100, which has passed through the bypass diode unit 510 and the capacitor unit 520. Particularly, the converter 530 can perform power conversion using DC power stored in the capacitor unit 520. The converter 530 according to an embodiment of the present invention will be described in more detail with reference to FIG. 6.

Switching elements in the converter 530 can be turned on/off based on a converter switching control signal from the controller 550. Accordingly, level-converted DC power can be output.

The inverter 540 can convert the DC power converted by the converter 530 into AC power. The figure shows a full-bridge inverter. That is, upper arm switching elements S1 and S3 connected in series and lower arm switching elements S2 and S4 connected in series are paired, and the two pairs of upper and lower arm switching elements S1, S2, S3 and S4 are connected in parallel. A diode can be connected in anti-parallel with each switching element S1 to S4.

The switching elements S1 to S4 in the inverter 540 can be turned on/off based on an inverter switching control signal from the controller 550. Accordingly, AC power having a predetermined frequency can be output. Desirably, AC power having the same frequency (about 60 Hz or 50 Hz) as the AC frequency of the grid is output.

The capacitor C can be disposed between the converter 530 and the inverter 540. The capacitor C can store the DC power having the level converted by the converter 530. Both terminals of the capacitor C can be called DC terminals and thus the capacitor C can be called a DC-terminal capacitor.

The input current detector A can detect input current ic1 supplied from the solar cell module 100 to the capacitor unit 520. The input voltage detector B can detect an input voltage Vol supplied from the solar cell module 100 to the capacitor unit 520. Here, the input voltage Vol can be the same as the voltage stored in the capacitor unit 520.

The detected input current ic1 and input voltage vc1 can be input to the controller 550.

The converter output current detector C detects output current ic2 from the converter 530, that is, DC-terminal current, and the converter output voltage detector D detects an output voltage vc2 from the converter 530, that is, a DC-terminal voltage. The detected output current ic2 and output voltage vc2 can be input to the controller 550.

The inverter output current detector E detects current ic3 output from the inverter 540 and the inverter output voltage detector F detects a voltage vc3 output from the inverter 540. The detected current ic3 and voltage vc3 are input to the controller 550.

The controller 550 can output control signals for controlling the switching elements of the converter 530. Particularly, the controller 550 can output a turn-on timing signal of the switching elements included in the converter 530 based on at least one of the detected input current ic1, input voltage vc1, output current ic2, output voltage vc2, output current ic3 and output voltage vc3.

Further, the controller 550 can output inverter control signals for controlling the switching elements S1 to S4 of the inverter 540. Particularly, the controller 550 can output a turn-on timing signal of the switching elements S1 to S4 of the inverter 540 based on at least one of the detected input current ic1, input voltage vc1, output current ic2, output voltage vc2, output current ic3 or output voltage vc3.

Further, the controller 550 can calculate a maximum power point with respect to the solar cell module 100 and control the converter 530 to output DC power corresponding to maximum power according thereto. The filter 570 can be disposed at the output terminals of the inverter 540.

In addition, the filter 570 can include a plurality of passive elements and adjust a phase difference between an AC current io and an AC voltage vo output from the inverter 540 based on at least some of the plurality of passive elements.

The first cable 31, which is connected to the grid cable oln, can be electrically connected to the output terminals of the filter 570. Further, the second cable 32 for data communication with the junction box 200 of the neighboring photovoltaic module 50 or the gateway 80 can be electrically connected to the controller 550. The controller 550 can perform data communication with the neighboring photovoltaic module 50 or the gateway 80. Particularly, the controller 550 can perform CAN communication.

CAN communication (Scan) can use a difference between a high level H and a low level L or a pulse width difference, as shown in FIG. 6. Although there is a pulse width difference in the figure, a high level and a low level can be varied. For CAN communication, a signal output from the controller 550 can be a differential signal. For CAN communication, the controller 550 can include a different signal generator for data communication.

The controller 550 performs data communication with the neighboring photovoltaic module 50 or the gateway 80 and need not be connected to the ground GND for data communication. Further, the controller 550 can transmit current information, voltage information and power information on the photovoltaic module 50 to the gateway 80.

Specifically, the controller 550 can output communication data including AC voltage information and AC information on output AC power to the outside through the second cable 32.

The controller 550 can receive an information transmission request signal from the neighboring photovoltaic module 50 or the gateway 80. The information transmission request signal can include a request for AC voltage information and AC information, a product information transmission request, or a network information request.

Upon reception of such an information transmission request, the controller 550 can output AC voltage information, AC information, product information or network information corresponding thereto to the outside through the second cable 32.

As described above, data communication can be easily performed using the controller 550 in the photovoltaic module 50 without an additional communication unit, thus reducing manufacturing costs of the photovoltaic module 50, particularly, the power conversion device. Furthermore, the photovoltaic module 50 can be easily installed because an additional ground for data communication is not needed.

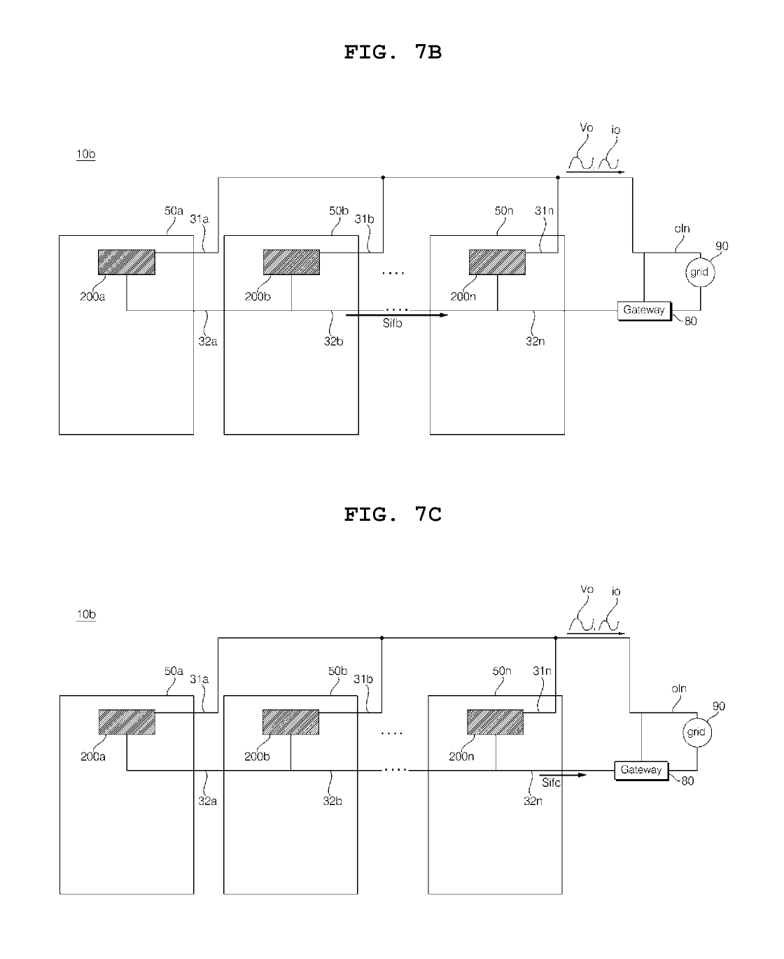

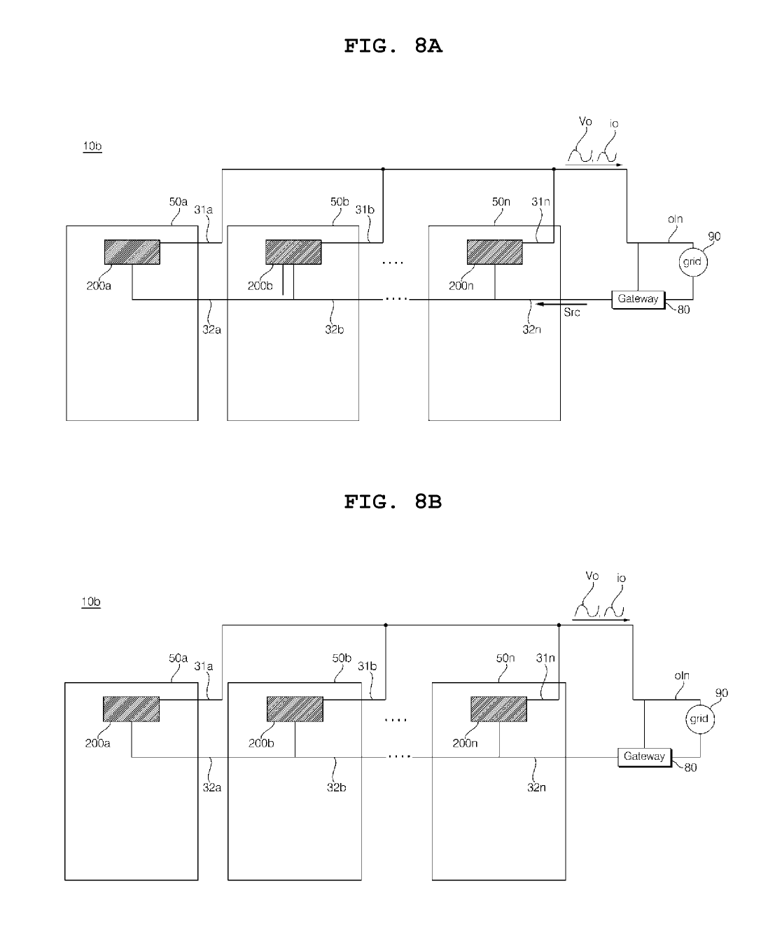

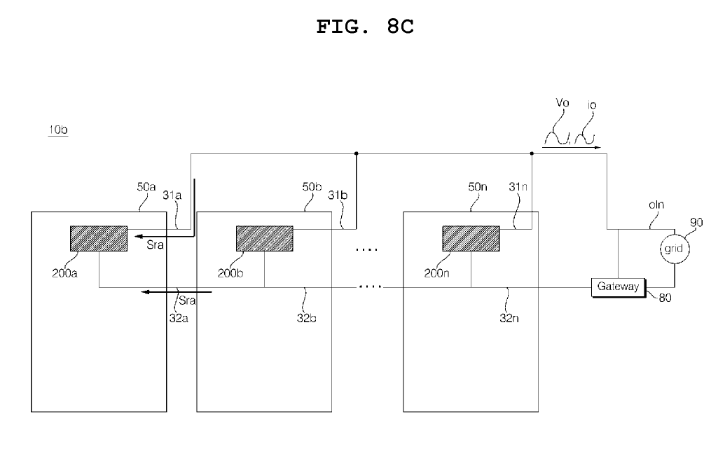

FIGS. 7A to 8C are diagrams referred to for describing a signal flow in CAN communication in the photovoltaic system 10b shown in FIG. 1B. For example, the controller 550a of the first photovoltaic module 50a among the plurality of photovoltaic modules 50a to 50n can output information Sifa on output AC power to the controller 550b of the neighboring second photovoltaic module 50b through the second cable 32a, as shown in FIG. 7A.

Accordingly, the controller 550b of the second photovoltaic module 50b can output information Sifb on output AC power and information on AC power output from the first photovoltaic module 50a to the controller 550c of the neighboring third photovoltaic module 50c through the second cable 32b, as shown in FIG. 7B.

Then, the controller 550n of the photovoltaic module 50n closest to the gateway 80 can output information Sifc on AC power output from the photovoltaic module 50n and information on AC power output from another photovoltaic module 50 to the gateway 80 through the second cable 32n. Accordingly, the gateway 80 can receive all pieces of information on the plurality of photovoltaic modules 50a to 50n.

Particularly, CAN communication can be performed using a controller of a neighboring photovoltaic module without direct communication between the farthest first photovoltaic module 50a and the gateway 80, and thus communication noise can be reduced and accurate data communication can be performed.

Alternatively, the controller 550n of the photovoltaic module 50n closest to the gateway 80 among the plurality of photovoltaic modules 50a to 50n can receive an information request signal Src on another photovoltaic module 50 from the gateway 80, as shown in FIG. 8A, and transmit received information request signal Srb to the controller 550b of another photovoltaic module 50b, as shown in FIG. 8B.

Subsequently, the controller 550b of the second photovoltaic module 50b can transmit an information request signal Sra on the first photovoltaic module 50a from the gateway 80 to the controller 550a of the first photovoltaic module 50a, as shown in FIG. 8C.

Then, the controller 550a of the first photovoltaic module 50a can transmit information corresponding to the information request signal Sra to the gateway 80 through the method described with reference to FIGS. 7A to 7C.

As described above, CAN communication can be performed using a controller of a neighboring photovoltaic module without direct communication between the farthest first photovoltaic module 50a and the gateway 80, and thus communication noise can be reduced and accurate data communication can be performed.

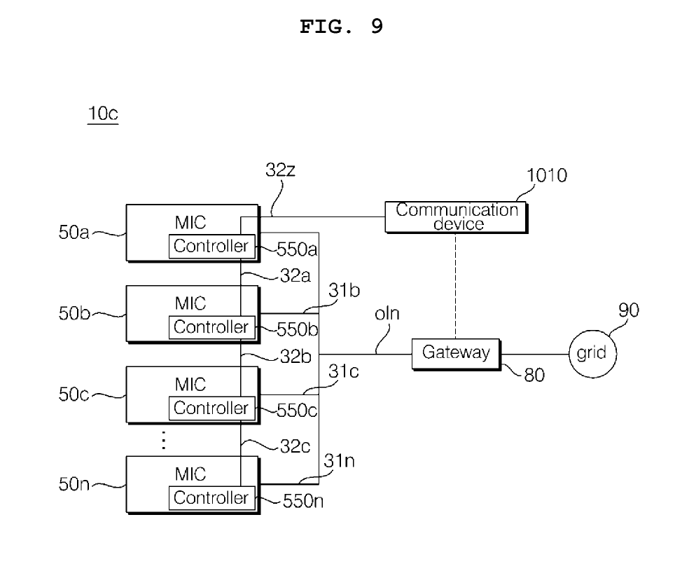

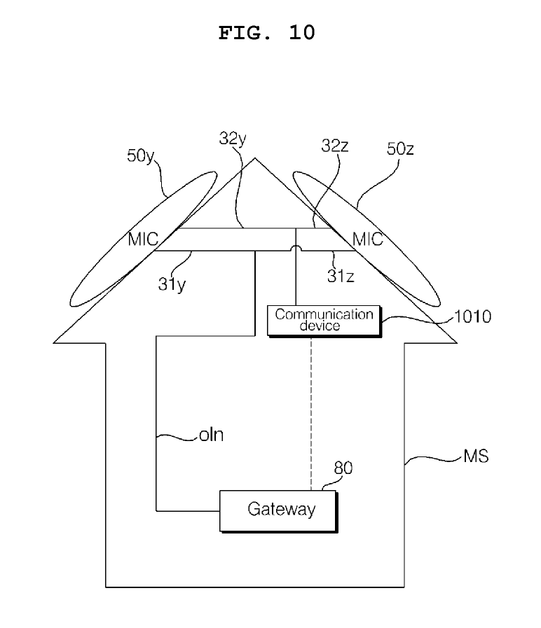

FIG. 9 shows a photovoltaic system according to another embodiment of the present invention and FIG. 10 is a diagram referred to for description of FIG. 9. Referring to the figures, the photovoltaic system 10c shown in FIG. 9 is similar to the photovoltaic system 10b shown in FIG. 1B but differs from the photovoltaic system 10b in that the former further includes a communication device 1010.

The photovoltaic system according to another embodiment of the present invention can include a plurality of photovoltaic modules 50a to 50n outputting AC power to a grid 90, the communication device 1010 performing data communication with the photovoltaic modules 50a to 50n, and a gateway 80 performing wireless communication with the communication device 1010.

The photovoltaic modules 50a to 50n output AC power to the grid cable oln through first cables 21a to 31n connected to junction boxes thereof. In addition, the photovoltaic modules 50a to 50n perform CAN communication through second cables 32a to 32n respectively connected to controllers 550a to 550n thereof. Here, the first photovoltaic module 50a, one of the photovoltaic modules 50a to 50n, can further include a second cable 32z for CAN communication with the communication device 1010.

The communication device 1010 can receive information on the photovoltaic modules 50a to 50n through the second cable 32z and transmit an information request to the photovoltaic modules 50a to 50n. The communication device 1010 can perform wireless communication with the gateway 80.

Accordingly, as shown in FIG. 10, the communication device 1010 can receive information on photovoltaic modules 50y and 50z installed outside a building MS through CAN communication using the second cables 32y and 32z, and the communication device 1010 and the gateway 80 installed inside of the building can perform wireless communication to easily receive information on the plurality of photovoltaic modules. Further, it is possible to easily request information on the plurality of photovoltaic modules. Also, first cables 31y and 31z are used through which AC power output from the photovoltaic modules 50y and 50z is output to the outside.

In addition, AC power generated in the plurality of photovoltaic modules is supplied to an internal grid through the grid cable oln.

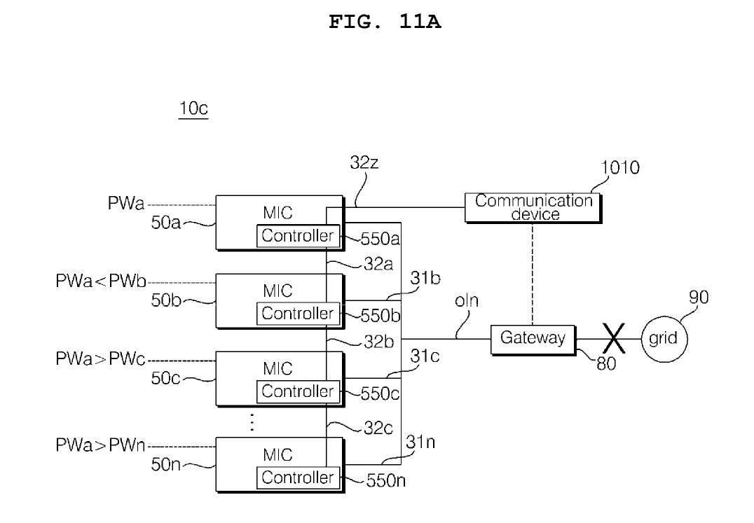

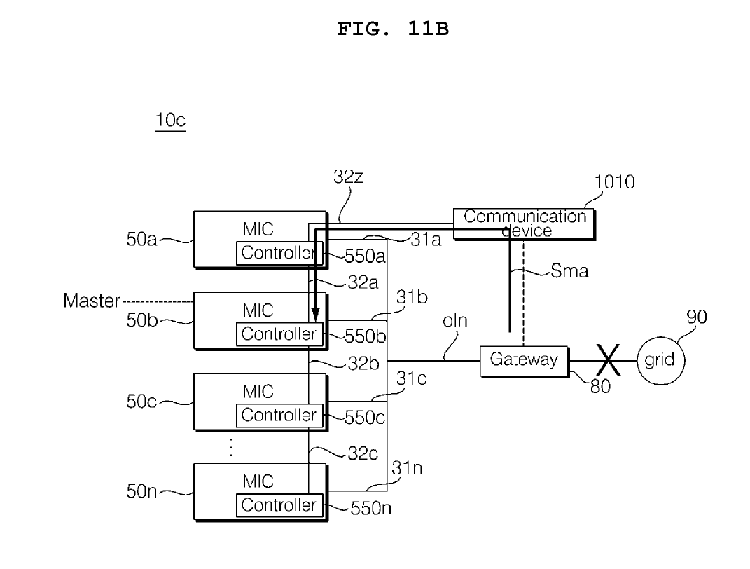

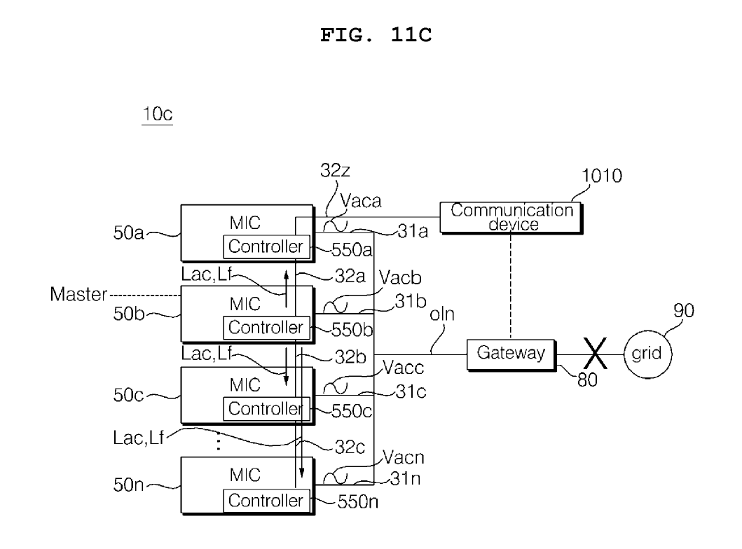

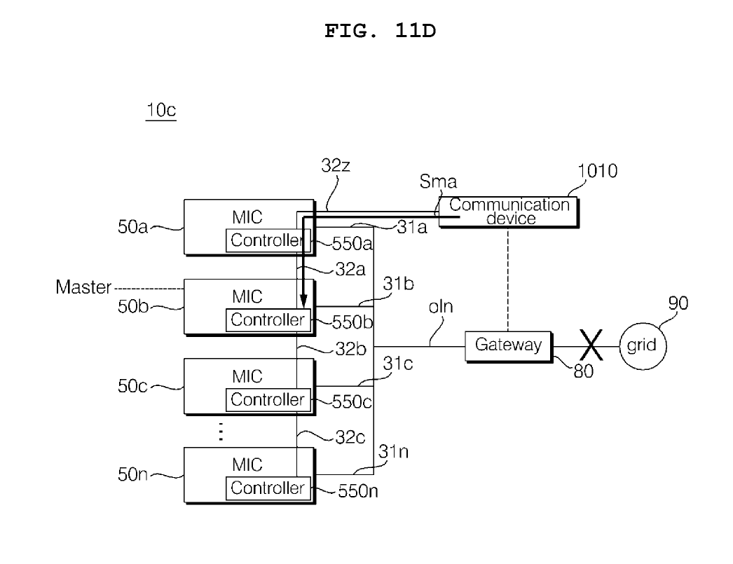

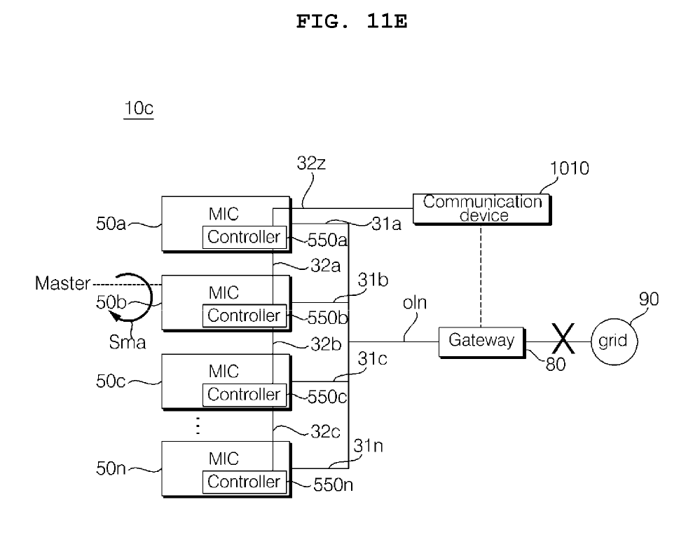

FIGS. 11A to 11E are diagrams referred to for describing the operation shown in FIG. 9. In particular, FIGS. 11A to 11E illustrate when the photovoltaic system 10c including the plurality of photovoltaic modules 50a to 50n, the communication device 1010 and the gateway 80 have been disconnected from the grid 90, particularly, when connection of the gateway 80 and the grid 90 is off. Such a case can be called off-grid.

On the other hand, when connection of the gateway 80 and the grid 90 is maintained can be called on-grid. When the photovoltaic system 10c is on-grid, the gateway 80 can transmit an AC power level, frequency information or phase information with respect to the grid 90 to the photovoltaic modules 50a to 50n and the communication device 1010 through CAN communication with the photovoltaic modules 50a to 50n and the communication device 1010. Accordingly, the photovoltaic modules 50a to 50n can stably output AC power to the grid.

When an off-grid situation occurs in the photovoltaic system 10c, the photovoltaic modules 50a to 50n do not have information on a reference AC power level, frequency or phase and thus need to determine the same.

FIG. 11A illustrates when connection of the gateway 80 and the grid 90 is off. In particular, FIG. 11A shows that the photovoltaic modules 50a to 50n respectively output powers Pwa, Pwb, Pwc, Pwn. Here, the power Pwb output from the second photovoltaic module 50b is highest.

The gateway 80 can receive information on AC power, particularly, power information on each photovoltaic module, through CAN communication with the photovoltaic modules 50a to 50n and select the second photovoltaic module 50b as a master photovoltaic module. Accordingly, the gateway 80 can transmit master setting information Sma to the second photovoltaic module 50b through CAN communication, as shown in FIG. 11B.

The second photovoltaic module 50b set as a master can transmit information Lac and Lf on AC power output through the first cable 31b of the second photovoltaic module 50b to a neighboring photovoltaic module through CAN communication. The information Lac and Lf on the AC power can include information on the level, frequency or phase of the AC power. Accordingly, the photovoltaic modules 50a to 50n can also stably output AC power in the photovoltaic system 10c based on the master photovoltaic module 50b in an off-grid situation.

Since CAN communication is performed between the photovoltaic modules 50a to 50n, the communication device 1010 and the gateway 80 in the photovoltaic system 10c, the communication device 1010 or any one of the photovoltaic modules instead of the gateway 80 can select the master photovoltaic module, as shown in FIGS. 11B and 11C, and AC voltages Vaca, Vacb, Vacc through Vacn are output.

FIG. 11D illustrates when the communication device 1010 selects the master photovoltaic module. The communication device 1010 can receive information on AC power, particularly, power information on each photovoltaic module, through CAN communication with the photovoltaic modules 50a to 50n and select the second photovoltaic module 50b as the master photovoltaic module.

Accordingly, the gateway 80 can transmit the master setting information Sma to the second photovoltaic module 50b through CAN communication, as shown in FIG. 11D.

FIG. 11E illustrates when the second photovoltaic module 50b which outputs highest power among the photovoltaic modules 50a to 50n selects the master photovoltaic module. The controller 550b in the second photovoltaic module 50b can receive information on AC power, particularly, power information on each photovoltaic module, through CAN communication with the photovoltaic modules 50a to 50n and select the second photovoltaic module 50b as the master photovoltaic module.

Accordingly, the gateway 80 can transmit the master setting information Sma to the second photovoltaic module 50b through CAN communication, as shown in FIG. 11E.

When any one of the photovoltaic modules 50a to 50n selects the master photovoltaic module in an off-grid situation in which the gateway 80 is not connected to the grid, as shown in FIG. 11E, the controller of the corresponding photovoltaic module can control the master photovoltaic module to be selected based on information on AC power output from neighboring photovoltaic modules and information on AC power output through the first cable and control the level, phase or frequency of AC power output from another photovoltaic module to be determined based on information on AC power output from the selected master photovoltaic module.

As described above, the master photovoltaic module can be selected in an off-grid situation and thus AC power can be stably output in the photovoltaic system 10c based on the selected master photovoltaic module.

FIG. 12 is an exploded perspective view of the solar cell module of FIG. 2. Referring to FIG. 12, the solar cell module 100 of FIG. 2 can include a plurality of solar cells 130. In addition, the solar cell module 100 can further include a first sealant 120 and a second sealant 150 provided on the upper surface and the lower surface of the solar cells 130, a rear substrate 110 provided under the first sealant 120, and a front substrate 160 provided on the second sealant 150.

The solar cell 130 is a semiconductor device which converts solar energy into electric energy and can be a silicon solar cell, a compound semiconductor solar cell, a tandem solar cell, a dye-sensitized solar cell, a CdTe solar cell, a CIGS solar cell or a thin film solar cell.

The solar cell 130 is formed on a light-receiving surface to which sunlight is input and a rear surface opposite the light-receiving surface. For example, the solar cell 130 can include a first conductivity type silicon substrate, a second conductivity type semiconductor layer which is formed on the silicon substrate and has a conductivity type opposite the first conductivity type, an antireflection film which includes at least one opening for partially exposing the second conductivity type semiconductor layer and is formed on the second conductivity type semiconductor layer, a front electrode contacting a portion of the second conductivity type semiconductor layer exposed through the at least one opening, and a rear electrode formed on the rear side of the silicon substrate.

The solar cells 130 can be electrically connected in series or parallel, or in serial-parallel. Specifically, the plurality of solar cells 130 can be electrically connected through the ribbon 133. The ribbon 133 can be attached to the front electrode formed on the light-receiving surface of a solar cell 130 and a rear electrode formed on the rear side of a neighboring solar cell 130. The figure shows that the ribbon 133 is formed in two lines and the solar cells 130 are connected in a row through the ribbon 133 to form a solar cell string 140.

In this manner, six strings 140a, 140b, 140c, 140d, 140e and 140f are formed and each string can include ten solar cells, as described above with reference to FIG. 2.

The rear substrate 110 is a back sheet and serves to execute waterproofing, insulation and sunblocking functions. The rear substrate 110 can be a Tedlar/PET/Tedlar (TPT) type but the present invention is not limited thereto. In addition, although the rear substrate 110 is rectangular in FIG. 4, the rear substrate 110 can be manufactured in various forms such as a circle and a semicircle according to environment in which the solar cell module 100 is installed.

The first sealant 120 can be attached to the rear substrate 110 having the same size as the rear substrate 110, and a plurality of solar cells 130 can be arranged in several rows on the first sealant 120. The second sealant 150 is positioned on the solar cells 130 and is attached to the first sealant 120 through lamination. Here, the first sealant 120 and the second sealant 150 are used to chemically connect elements of the solar cells. Various materials such as ethylene vinyl acetate (EVA) film can be used as the first sealant 120 and the second sealant 150.

The front substrate 160 is positioned on the second sealant 150 such that sunlight is transmitted through the front substrate 160. It is desirable that the front substrate 160 be tempered glass in order to protect the solar cells 130 from external impact, but other materials can be used. It is more desirable that the front substrate 160 be low-iron tempered glass in order to prevent reflection of sunlight and to improve transmissivity of sunlight.

As is apparent from the above description, according to an embodiment of the present invention, the photovoltaic module and the photovoltaic system including the same comprise a solar cell module including a plurality of solar cells, a junction box which converts DC power from the solar cell module to AC power, a first cable through which the AC power from the junction box is output to an outside, and a second cable which is connected to a controller in the junction box and used for output or input of communication data. Accordingly, data communication can be easily performed using a controller included in a photovoltaic module.

The controller can perform data communication with a neighboring photovoltaic module or a gateway, and a signal output from the controller can be a differential signal. Accordingly, data communication can be easily performed without an additional communication unit.

Further, the controller performs data communication with a neighboring photovoltaic module or a gateway and is not connected to the ground for data communication. Accordingly, the ground for data communication is not required and thus the photovoltaic module can be easily installed.

The controller can output communication data including AC voltage information and AC information on output AC power to the outside through the second cable, and thus information on the photovoltaic module which is an AC module can be easily output to the outside.

The photovoltaic system according to another embodiment of the present invention includes a plurality of photovoltaic modules to output AC power to a grid, a communication device which performs data communication with the plurality of photovoltaic modules, and a gateway which performs data communication with the communication device, wherein each photovoltaic module includes a solar cell module including a plurality of solar cells, a junction box which converts DC power from the solar cell module to output AC power, a first cable through which the AC power from the junction box is output to the outside, and a second cable which is connected to a controller in the junction box and used for output/input of communication data to/from the communication device. Accordingly, data communication can be easily performed using a controller in a photovoltaic module.

Particularly, a gateway installed indoors can easily receive information on a photovoltaic module installed outdoors through wireless communication between the communication device and the gateway. The photovoltaic module according to the present invention is not limited to the above-described embodiments and all or some of the embodiments can be selectively combined such that the embodiments can be modified in various manners.

Although the example embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A photovoltaic module comprising:
a solar cell module including a plurality of solar cells;
a junction box to convert DC power from the solar cell module to AC power;
a first cable through which the AC power from the junction box is output to an outside; and
a second cable connected to a controller in the junction box for output or input of communication data.

2. The photovoltaic module according to claim 1, wherein the first cable is connected to a grid cable connected to a grid, and the second cable is connected to a junction box of a neighboring photovoltaic module or a gateway.

3. The photovoltaic module according to claim 1, further comprising a controller configured to perform data communication with a neighboring photovoltaic module or a gateway.

4. The photovoltaic module according to claim 3, wherein the controller includes a differential signal generator for generating a differential signal for the data communication.

5. The photovoltaic module according to claim 3, wherein the controller is not connected to a ground for the data communication.

6. The photovoltaic module according to claim 3, wherein the controller outputs the communication data including AC voltage information and AC information on the AC power that is output, to the outside through the second cable.

7. The photovoltaic module according to claim 3, wherein the controller receives an information transmission request signal through the second cable.

8. The photovoltaic module according to claim 1, wherein the junction box comprises:
a converter to convert a level of the DC power input from the solar cell module;
a DC-terminal capacitor to store the DC power output from the converter;
an inverter including a plurality of switching elements and to convert the DC power from the DC-terminal capacitor into the AC power; and
the controller controlling the inverter and performing data communication.

9. The photovoltaic module according to claim 8, further comprising a filter to filter the AC power output from the inverter,
wherein the first cable is electrically connected to an output terminal of the filter.

10. The photovoltaic module according to claim 3, wherein the controller controls a master photovoltaic module to be selected based on information on AC power output from a neighboring photovoltaic module and information on the AC power of the solar cell module output through the first cable and controls the level, phase or frequency of AC power output from another photovoltaic module to be determined based on information on AC power output from the selected master photovoltaic module when the gateway is not connected to a grid.

11. A photovoltaic system comprising:
a plurality of photovoltaic modules to output AC power to a grid; and
a gateway to perform data communication with the plurality of photovoltaic modules,
wherein each photovoltaic module comprises:
a solar cell module including a plurality of solar cells;
a junction box to convert DC power from the solar cell module to AC power;
a first cable through which the AC power from the junction box is output to an outside; and
a second cable connected to a controller in the junction box for output or input of communication data.

12. The photovoltaic system according to claim 11, wherein the first cable is connected to a grid cable connected to the grid, and the second cable is connected to a junction box of a neighboring photovoltaic module or the gateway.

13. The photovoltaic system according to claim 11, wherein each photovoltaic module includes a controller configured to perform data communication with a neighboring photovoltaic module or the gateway.

14. The photovoltaic system according to claim 13, wherein the controller is not connected to a ground for the data communication.

15. The photovoltaic system according to claim 13, wherein the controller outputs the communication data including AC voltage information and AC information on the AC power that is output, to the outside through the second cable.

16. The photovoltaic system according to claim 11, wherein a controller of a first photovoltaic module among the plurality of photovoltaic modules outputs information on the AC power that is output, to a controller of a neighboring second photovoltaic module through the second cable, and the controller of the second photovoltaic module outputs information on the AC power that is output, and information on AC power that is output, from the first photovoltaic module to a controller of a neighboring third photovoltaic module.

17. The photovoltaic system according to claim 16, wherein the controller of the second photovoltaic module transmits an information request signal with respect to the first photovoltaic module from the gateway to the controller of the first photovoltaic module.

18. The photovoltaic system according to claim 11, wherein a controller of a photovoltaic module among the plurality of photovoltaic modules closest to the gateway outputs information on AC power output from the photovoltaic module and information on AC power output from other photovoltaic modules.

19. The photovoltaic system according to claim 11, wherein a controller of a photovoltaic module among the plurality of photovoltaic modules closest to the gateway receives an information request signal with respect to another photovoltaic module and transmits the received information request signal to the controller of the other photovoltaic module.

20. A photovoltaic system comprising:
a plurality of photovoltaic modules to output AC power to a grid;
a communication device to perform data communication with the plurality of photovoltaic modules; and
a gateway to perform data communication with the communication device,
wherein each photovoltaic module comprises:
a solar cell module including a plurality of solar cells;
a junction box to convert DC power from the solar cell module to AC power;
a first cable through which the AC power from the junction box is output to an outside; and
a second cable connected to a controller in the junction box and used for output/input of communication data to/from the communication device.
